(19) United States
(12) Patent Application Publication
(10) Pub. No.: US 2025/0071990 A1
(43) Pub. Date: Feb. 27, 2025

(54) MEMORY DEVICE AND MANUFACTURING METHOD OF THE MEMORY DEVICE

(71) Applicant: SK hynix Inc., Icheon-si Gyeonggi-do (KR)

(72) Inventor: Jae Ho KIM, Icheon-si Gyeonggi-do (KR)

(73) Assignee: SK hynix Inc., Icheon-si Gyeonggi-do (KR)

(21) Appl. No.: 18/545,325

(22) Filed: Dec. 19, 2023

(30) Foreign Application Priority Data
Aug. 23, 2023 (KR) 10-2023-0110420

(51) Int. Cl. H10B 43/27

(52) U.S. Cl. CPC H10B 43/27

(57) ABSTRACT

A memory device including: a first stack structure including conductive layers stacked along a first direction, the first stack structure having a stepped structure defined by end portions of the conductive layers; contact plugs respectively connected to the conductive layers, the contact plugs extending along the first direction, the contact plugs extending to the inside of the first stack structure; and dummy layers located between the contact plugs.

### CROSS-REFERENCE TO RELATED APPLICATION

The present application claims priority under 35 U.S.C. § 119(a) to Korean patent application number 10-2023-0110420 filed on Aug. 23, 2023, in the Korean Intellectual Property Office, the entire disclosure of which is incorporated by reference herein.

### BACKGROUND

### 1. Technical Field

The present disclosure generally relates to a memory device and a manufacturing method of the memory device, and more particularly, to a memory device including a memory block having a three-dimensional structure and a manufacturing method of the memory device.

### 2. Related Art

A memory device may include a nonvolatile memory device in which stored data is retained as it is even when power supply is interrupted. The nonvolatile memory device may be divided into a two-dimensional structure and a three-dimensional structure according to a structure in which memory cells are arranged. Memory cells of a nonvolatile memory device having a two-dimensional structure may be arranged in a single layer above a substrate, and memory cells of a non-volatile memory device having a three-dimensional structure may be stacked in a vertical direction above a substrate. Because a degree of integration of the nonvolatile memory device having the three-dimensional structure is higher than a degree of integration of the nonvolatile memory device having the two-dimensional structure, electronic devices using the nonvolatile memory device having the three-dimensional structure have recently been increasingly used.

### SUMMARY

In accordance with an embodiment of the present disclosure, there is provided a memory device including: a first stack structure including conductive layers stacked along a first direction, the first stack structure having a stepped structure defined by end portions of the conductive layers; contact plugs respectively connected to the conductive layers, the contact plugs extending along the first direction, the contact plugs extending to the inside of the first stack structure; and dummy layers located between the contact plugs.

In accordance with an embodiment of the present disclosure, there is provided a method of manufacturing a memory device, the method including: forming a first preliminary stack structure including first material layers and second material layers, which are alternately stacked, the first preliminary stack structure having a stepped structure defined by end portions of the second material layers; forming a cover pattern on top surfaces of the end portions of the second material layers; forming a second preliminary stack structure by alternately stacking first dummy material layers and second dummy material layers, which respectively extend along the end portions on the stepped structure; forming a first opening penetrating the first preliminary stack structure and the second preliminary stack structure; forming a recess by removing a portion of each of the second material layers and the second dummy material layers, which are exposed through the first opening; forming a spacer layer in the first opening and the recess; forming a second opening penetrating the spacer layer; forming a third opening by removing the cover pattern through the second opening; and forming a contact plug by filling a conductive material in the second opening and the third opening.

### BRIEF DESCRIPTION OF THE DRAWINGS

Various embodiments will now be described more fully hereinafter with reference to the accompanying drawings; however, they may be embodied in different forms and should not be construed as limited to the embodiments set forth herein.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory device in accordance with an embodiment of the present disclosure.

FIG. 2 is a view schematically illustrating a memory device in accordance with an embodiment of the present disclosure.

FIG. 3 is a view illustrating a cell region and a contact region of a memory device in accordance with an embodiment of the present disclosure.

FIGS. 4A, 4B, and 4C are views illustrating a structure of a memory device in accordance with an embodiment of the present disclosure.

FIGS. 5A, 5B, 5C, 5D, 5E, 5F, 5G, 5H, 5I, 5J, 5K, 5L, and 5M are views illustrating a manufacturing method of a memory device in accordance with an embodiment of the present disclosure.

FIG. 6 is a diagram illustrating a memory card system to which the memory device of the present disclosure is applied.

FIG. 7 is a diagram illustrating a Solid State Drive (SSD) system to which the memory device of the present disclosure is applied.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Hereinafter, embodiments of the present disclosure will be described in detail with reference to the accompanying drawings in order for those skilled in the art to be able to readily implement the technical spirit of the present disclosure. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

Various embodiments provide a memory device and a manufacturing method of the memory device, which can minimize shape distortion of a contact plug.

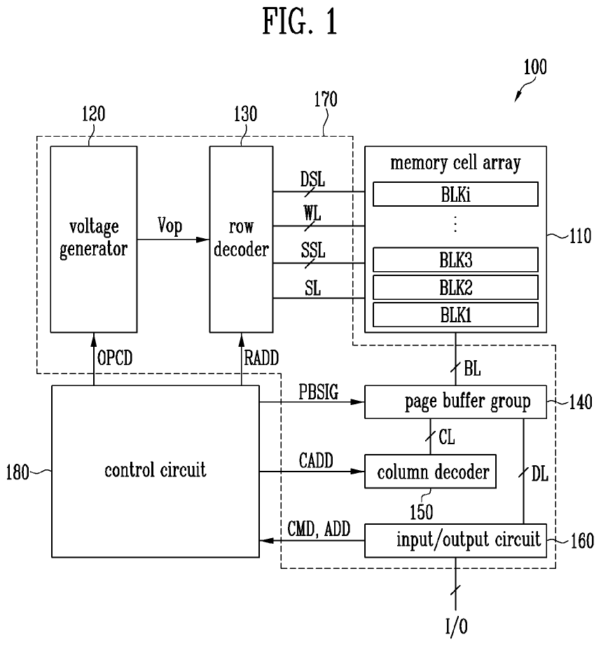

FIG. 1 is a diagram illustrating a memory device in accordance with an embodiment of the present disclosure.

Referring to FIG. 1, the memory device 100 may include a memory cell array 110, a peripheral circuit 170, and a control circuit 180.

The memory cell array 110 may include first to ith memory blocks BLK1 to BLKi. Each of the first to ith memory blocks BLK1 to BLKi may include memory cells capable of storing data. Drain select lines DSL, word lines WL, source select lines SSL, and a source line SL may be connected to each of the first to ith memory blocks BLK1 to BLKi, and bit lines BL may be commonly connected to the first to ith memory blocks BLK1 to BLKi.

The first to ith memory blocks BLK1 to BLKi may be formed in a three-dimensional structure. The memory blocks having the three-dimensional structure may include memory cells stacked in a vertical direction above a substrate.

The memory cells may store one-bit or two-or-more-bit data according to a program manner. For example, a manner in which one-bit data is stored in one memory cell is referred to as a single level cell (SLC) manner, and a manner in which two-bit data is stored in one memory cell is referred to as a multi-level cell (MLC) manner. A manner in which three-bit data is stored in one memory cell is referred to as a triple level cell (TLC) manner, and a manner in which four-bit data is stored in one memory cell is referred to as a quad level cell (QLC) manner. In addition, five-or-more-bit data may be stored in one memory cell.

The peripheral circuit 170 may be configured to perform a program operation for storing data, a read operation for outputting data stored in the memory cell array 110, and an erase operation for erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop used for a program operation, a read operation, or an erase operation in response to an operation code OPCD. For example, the voltage generator 120 is configured to generate program voltages, turn-on voltages, turn-off voltages, negative voltages, precharge voltages, verify voltages, read voltages, pass voltages, or erase voltages in response to the operation code OPCD. The operating voltages Vop generated by the voltage generator 120 may be applied to drain select lines DSL, word lines WL, source select lines SSL, and a source line SL of a selected memory block through the row decoder 130.

The program voltages are voltages applied to a selected word line among word lines WL in a program operation, and may be used to increase a threshold voltage of memory cells connected to the selected word line. The turn-on voltages may be applied to the drain select lines DSL or the source select lines SSL, and be used to turn on drain select transistors or source select transistors. The turn-off voltages may be applied to the drain select lines DSL or the source select lines SSL, and be used to turn off the drain select transistors or the source select transistors. For example, the turn-off voltage may be set to 0V. The precharge voltages are voltages higher than 0V, and may be applied to the bit lines in a read operation. The verify voltages may be used in a verify operation for determining whether a threshold voltage of selected memory cells has been increased to a target level. The verify voltages may be set to various levels according to the target level, and be applied to a selected word line.

The read voltages may be applied to a selected word line in a read operation of selected memory cells. For example, the read voltages may be set to various levels according to a program manner of the selected memory cells. The pass voltages are voltages applied to unselected word lines among the word lines WL in a program or read operation, and may be used to turn on memory cells connected to the unselected word lines. The erase voltages may be used in an erase operation for erasing memory cells included in a selected memory block, and be applied to the source line SL.

The row decoder 130 may be configured to transmit the operating voltages Vop to drain select lines DSL, word lines WL, source select lines SSL, and a source line SL, which are connected to a selected memory block, according to a row address RADD. For example, the row decoder 130 may be connected to the voltage generator 120 through global lines, and may be connected to the first to ith memory blocks BLK1 to BLKi through the drain select lines DSL, the word lines WL, the source select lines SSL, and the source line SL.

The page buffer group 140 may include page buffers (not shown) connected to each of the first to ith memory blocks BLK1 to BLKi. The page buffers (not shown) may be connected to the first to ith memory blocks BLK1 to BLKi respectively through the bit lines BL. In a read operation, the page buffers (not shown) may sense a current or a voltage of the bit lines BL, which varies according to threshold voltages of selected memory cells, and store sensed data, in response to page buffer control signals PBSIG.

The column decoder 150 may be configured to transmit data between the page buffer group 140 and the input/output circuit 160 in response to a column address CADD. For example, the column decoder 150 may be connected to the page buffer group 140 through column lines CL, and transmit enable signals through the column lines. The page buffers (not shown) included in the page buffer group 140 may receive or output data through data lines DL in response to the enable signals.

The input/output circuit 160 may be configured to receive or output a command CMD, an address ADD, or data through input/output lines I/O. For example, the input/output circuit 160 may transmit, to the control circuit 180, a command CMD and an address ADD, which are received from an external controller, through the input/output lines I/O, and transmit data received from the external controller to the page buffer group 140 through the input/output lines I/O. Alternatively, the input/output circuit 160 may output data transferred from the page buffer group 140 to the external controller through the input/output lines I/O.

The control circuit 180 may output at least one of an operation code OPCD, the row address RADD, the page buffer control signals PBSIG, and the column address CADD in response to the command CMD and the address ADD. For example, when the command CMD input to the control circuit 180 is a command corresponding to a program operation, the control circuit 180 may control the peripheral circuit 170 to perform a program operation of a memory block selected by the address ADD. When the command CMD input to the control circuit 180 is a command corresponding to a read operation, the control circuit 180 may control the peripheral circuit 170 to perform the read operation of the selected memory block selected and output read data. When the command CMD input to the control circuit 180 is a command corresponding to an erase operation, the control circuit 180 may control the peripheral circuit 170 to perform the erase operation of the selected memory block.

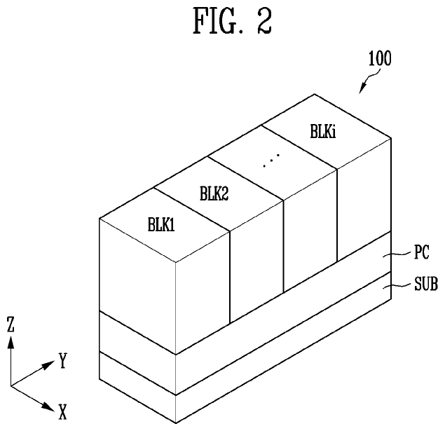

FIG. 2 is a view schematically illustrating a memory device in accordance with an embodiment of the present disclosure.

Referring to FIG. 2, the memory device 100 may include a peripheral circuit structure PC and memory blocks BLK1 to BLKi, which are disposed on a substrate SUB. The memory blocks BLK1 to BLKi may overlap with the peripheral circuit structure PC.

The substrate SUB may be a single crystalline semiconductor layer. For example, the substrate SUB may be a bulk silicon substrate, a silicon on insulator substrate, a germanium substrate, a germanium on insulator substrate, a silicon-germanium substrate, or an epitaxial thin film formed through a selective epitaxial growth process.

The peripheral circuit structure PC may include a row decoder (130 shown in FIG. 1), a column decoder (150 shown in FIG. 1), a page buffer group (140 shown in FIG. 1), a control circuit (180 shown in FIG. 1), and the like, which constitute a circuit for controlling operations of the memory blocks BLK1 to BLKi. For example, the peripheral circuit structure PC may include an NMOS transistor, a PMOS transistor, a resistor, a capacitor, and the like, which are electrically connected to the memory blocks BLK1 to BLKi. The peripheral circuit structure PC may be disposed between the substrate SUB and the memory blocks BLK1 to BLKi.

Each of the memory blocks BLK1 to BLKi may include a source structure, bit lines, cell strings electrically connected to the source structure and the bit lines, word lines electrically connected to the cell strings, and select lines electrically connected to the cell strings. Each of the cell strings may include memory cells and select transistors, which are connected in series by a cell plug. Each of the select lines may be used as a gate electrode of a select transistor corresponding thereto, and each of the word lines may be used as a gate electrode of a memory cell corresponding thereto.

In another embodiment, the substrate SUB, the peripheral circuit structure PC, and the memory blocks BLK1 to BLKi may be stacked in a reverse order of the order shown in FIG. 2. For example, the peripheral circuit structure PC may be disposed on the memory blocks BLK1 to BLKi.

In another embodiment, unlike as shown in FIG. 2, the peripheral circuit structure PC may be disposed on a partial region of the substrate SUB, which does not overlap with the memory blocks BLK1 to BLKi. For example, the peripheral circuit structure PC and the memory blocks BLK1 to BLKi may be respectively disposed on regions of the substrate SUB, which do not overlap with each other.

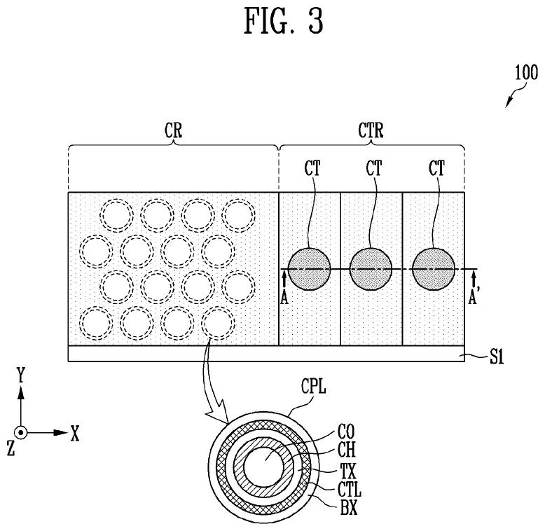

FIG. 3 is a view illustrating a cell region and a contact region of a memory device in accordance with an embodiment of the present disclosure. FIG. 3 is a plan view illustrating a layout of a cell region CR and a contact region CTR of the memory device 100.

Referring to FIG. 3, the memory device may include the cell region CR and the contact region CTR. For example, the contact region CTR may extend in an X direction from the cell region CR. Unlike the illustration of FIG. 3, the contact region CTR may extend in a Y direction from the cell region CR, or extend in the X direction and the Y direction. In addition, the cell region CR and the contact region CTR may be variously disposed.

Cell plugs CPL may be located in the cell region CR. The cell plugs CPL may be formed in the cell region CR. The cell plugs CPL may be arranged in the X direction and the Y direction in the cell region CR. Each of the cell plugs CPL may extend in a Z direction. Each of the cell plugs CPL may include a blocking layer BX, a charge trap layer CTL formed along an inner wall of the blocking layer BX, a tunnel insulating layer TX formed along an inner wall of the charge trap layer CTL, a channel layer CH formed along an inner wall of the tunnel insulating layer TX, or a core pillar CO inside the channel layer CH, or include a combination of at least two thereof. The blocking layer BX and the tunnel insulating layer TX may be formed of an oxide layer. For example, the blocking layer BX and the tunnel insulating layer TX may be formed of a silicon oxide layer or a silicon nitride layer, or be formed of a combination thereof. The charge trap layer CTL may be formed of a nitride layer or a variable resistance material. The channel layer CH may be formed of a conductive layer, e.g., a doped silicon layer. The channel layer CH may be replaced with an electrode structure. The core pillar CO may be formed of an insulating layer or a conductive layer. Each of the blocking layer BX, the charge trap layer CTL, the tunnel insulating layer TX, the channel layer CH, and the core pillar CO, which are included in the cell plug CPL, may extend in the Z direction. In an embodiment, a capping layer for improving electrical characteristics of select transistors included in each cell string may be further formed on the top of the core pillar CO.

Contact plugs CT may be located in the contact region CTR. The contact plugs CT may be formed in the contact region CTR. The contact plugs CT may be arranged along the X direction in the contact region CTR. Apart from the illustration of FIG. 3, the contact plugs CT may be arranged along the Y direction in the contact region CTR. Alternatively, some of the contact plugs may be arranged along the X direction, and the others of the contact plugs CT may be arranged along the Y direction. Each of the contact plugs CT may extend in the Z direction.

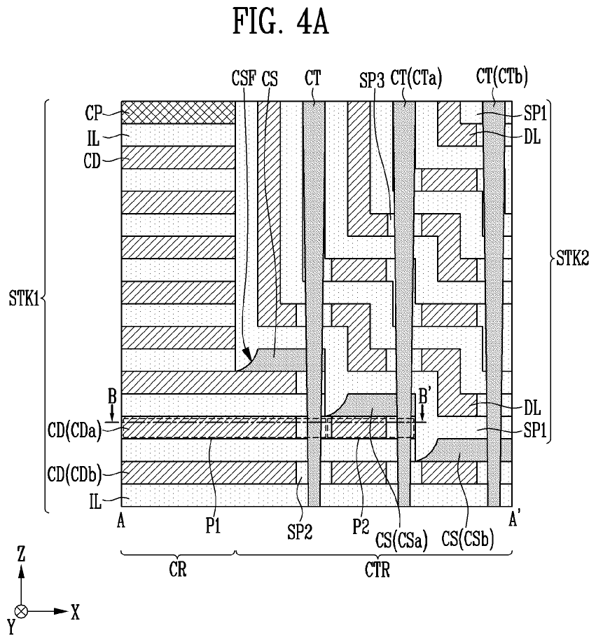

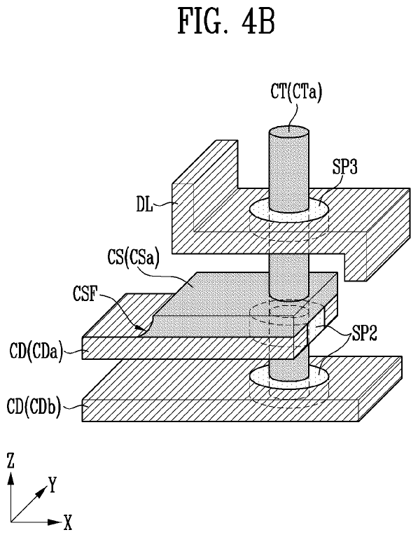

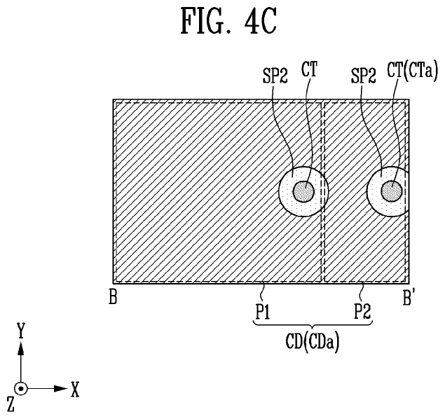

The numbers of the cell plugs CPL and the contact plugs CT are not limited by the illustration of FIG. 3. For example, the number of contact plugs CT may vary according to a stacked number of layers included in the memory device 100. In addition, the positions of the cell plugs CPL and the contact plugs CT are not limited by the illustration of FIG. 3, and the cell plugs CPL and the contact plugs CT may be located at various positions as long as the cell plugs CPL and the contact plugs CT include features described in FIGS. 4A to 4C.

The memory device 100 may include a slit S1. The slit S1 may extend in the Z direction and extend in the X direction. The slit S1 may divide the memory device 100 into a plurality of regions each including the cell region CR and the contact region CTR. For example, the slit S1 may isolate the first to ith memory blocks BLK1 to BLKi shown in FIG. 2 from each other.

FIGS. 4A to 4C are views illustrating a structure of a memory device in accordance with an embodiment of the present disclosure. FIG. 4A is a sectional view illustrating a section taken along line A-A′ shown in FIG. 3. FIG. 4B is a perspective view illustrating a portion of the memory device 100 shown in FIG. 4A. FIG. 4C is a sectional view illustrating a section taken along line B-B′ shown in FIG. 4A.

Referring to FIG. 4A, the memory device 100 may include a first stack structure STK1. The first stack structure STK1 may include conductive layers CD stacked along the Z direction. Interlayer insulating layers IL may be located between the conductive layers CD. The conductive layers CD and the interlayer insulating layers IL may be alternately stacked along the Z direction. The first stack structure STK1 may extend in the X direction and the Y direction. The conductive layers CD may be formed of tungsten (W), cobalt (Co), nickel (Ni), molybdenum (Mo), silicon (Si) or poly-silicon (poly-Si), or be formed of a combination of at least two thereof. The interlayer insulating layers IL may be formed of an oxide layer (e.g., a silicon oxide layer).

Each of the conductive layers CD may include an interposition portion P1 and an end portion P2 extending from the interposition portion P1. The interposition portion P1 of each of the conductive layers CD may be disposed between interlayer insulating layers IL adjacent to each other in the Z direction. The end portion P2 of each of the conductive layers CD may extend in the X direction from the interposition portion P1. For example, a region of any one conductive layer CDa, which overlaps with an interlayer insulating layer IL at a top end thereof, may correspond to the interposition portion P1, and the other region of the one conductive layer CDa may correspond to the end portion P2. In another example, a region of any one conductive layer CDb, which overlap with another conductive layer CDa, may correspond to the interposition portion P1, and a region of the one conductive layer CDb, which does not overlap with the another conductive layer CDa, may correspond to the end portion P2. However, for convenience of description, the interposition portion P1 and the end portion P2 are described while being distinguished from each other, and may physically extend to each other.

The first stack structure STK1 may have a stepped structure defined by the end portions P2 of the conductive layers CD. For example, the stepped structure defined by the end portions P2 of the conductive layers CD may be formed in the contact region CTR of the memory device 100. The end portions P2 of the conductive layers CD may correspond to respective steps of the stepped structure. Top surfaces of the end portions P2 may correspond to a top surface of the stepped structure of the first stack structure STK1. Referring to FIGS. 4A and 4B together, because lengths of the conductive layers CD in the X direction are different from each other, the stepped structure may be defined by the end portions P2 of the conductive layers CD.

A cover pattern CP may be disposed on a portion of a top surface of the first stack structure STK1. The cover pattern CP may cover the portion of the top surface of the first stack structure STK1. For example, the cover pattern CP may cover a top surface of the cell region CR of the first stack structure STK1.

Connection structures CS may be formed on the top surfaces of the end portions P2 of the conductive layers CD. The connection structures CS may be in contact with the top surfaces of the end portions P2 of the conductive layers CD, respectively. The connection structures CS may be electrically connected to the conductive layers CD. For example, referring to FIGS. 4A and 4B together, any one connection structure CSa may cover a portion of a top surface of any one conductive layer CDa. The connection structures CS may be formed of tungsten (W), cobalt (Co), nickel (Ni), molybdenum (Mo), silicon (Si) or poly-silicon (poly-Si), or be formed of a combination of at least two thereof.

The connection structures CS may be formed to be spaced apart from each other. For example, any one connection structure CSa may be spaced apart from another connection structure CSb. The connection structures CS may be formed not to overlap with each other. For example, the connection structures CSa and CSb might not overlap with each other. The connection structures CS may be formed on the respective steps included in the stepped structure of the first stack structure STK1.

Each of the connection structures CS may include a concave surface CSF recessed from a side surface of the first stack structure STK1. Each of the connection structures CS may include the concave surface CSF such that the concave surface CSF is in contact with a top surface of each of the steps of the first stack structure STK1 and is not in contact with a side surface of each of the steps. The concave surface CSF of the connection structure CS may be formed at a side surface located in the opposite direction of the X direction among side surfaces of the connection structure CS. By the concave surfaces CSF, the connection structures CS may prevent or mitigate the conductive layers CD from being connected to each other. For example, any one connection structure CSb is connected to any one conductive layer CDb, but might not be connected to another conductive layer CDa. Because the connection structure CSb includes a concave surface CSF, the connection structure CSb may be prevented or mitigated from being in contact with a side surface of the another conductive layer CDa. In FIG. 4A, it is illustrated that the section of the concave surface CSF has an arc shape (or the section of a recess has a fan shape). However, the present disclosure is not limited thereto. For example, as long as the connection structures CS are not in contact with side surfaces of the conductive layers CD, the section of the concave surface CFS may have a line shape or a curved line shape, and the section of the recess may have a triangular shape or a quadrangular shape. In the present disclosure, the recess may mean a region between the concave surface CSF and the side surface of the first stack structure STK1.

The memory device 100 may include a second stack structure STK2. The second stack structure STK2 may be disposed on the stepped structure of the first stack structure STK1. The second stack structure STK2 may overlap with at least a portion of the first stack structure STK1. The second stack structure STK2 may cover the stepped structure of the first stack structure STK1.

The second stack structure STK2 may include dummy layers DL located on the stepped structure of the first stack structure STK1. First spacers SP1 may be located between the dummy layers DL. The dummy layers DL and the first spacers SP1 may be alternately stacked along the Z direction. The second stack structure STK2 may extend along the X direction and the Y direction. The dummy layers DL may include a conductive material. The dummy layer DL may be formed of tungsten (W), cobalt (Co), nickel (Ni), molybdenum (Mo), silicon (Si) or poly-silicon (poly-Si), or be formed of a combination of at least two thereof. For example, the dummy layers DL may be formed of the same material as the conductive layers CD. In addition, the first spacers SP1 may be formed of an oxide layer (e.g., a silicon oxide layer).

The dummy layers DL and the first spacers SP1 may be formed along the stepped structure of the first stack structure STK1. For example, the dummy layers DL and the first spacers SP1 may extend along the end portions P2 of the conductive layers CD, respectively. Referring to FIGS. 4A and 4B together, at least one dummy layer DL may have a stepped shape corresponding to the stepped structure of the first stack structure STK1. For example, unlike the stepped structure of the first stack structure STK1, in which end portions P2 of different conductive layers CD constitute different steps, each of the dummy layers DL and the first spacers SP1 may extend while forming a step in the second stack structure STK2.

A first spacer SP1 at a lowermost end among the first spacers SP1 may be in contact with the first stack structure STK1 and connection structures CS. The first spacer SP1 may be in contact with a side surface of the cell region CR of the first stack structure STK1. Also, the first spacer SP1 may be formed on the contact region CTR of the first stack structure STK1. The first spacer SP1 may be formed along top surfaces and side surfaces of the connection structures CS. The first spacer SP1 may fill recesses which the connection structures CS include. Therefore, the first spacer SP1 may be in contact with concave surfaces CSF of the connection structures CS.

The memory device 100 may include contact plugs CT electrically connected respectively to the conductive layers CD. Because the contact plugs CT are respectively spaced apart from the conductive layers CD but are in contact with the connection structures CS, the contact plugs CT may be electrically connected to the conductive layers CD through the connection structures CS. For example, referring to FIGS. 4A and 4B together, a contact plug CTa is in contact with a connection structure CSa but might not be in contact with a conductive layer CDa. The contact plug CTa may be connected to the conductive layer CDa through the connection structure CSa. The contact plugs CT may be integrally formed with the connection structures CS. In FIGS. 4A and 4B, for convenience of description, it is illustrated that the contact plugs CT and the connection structures CS are as if they are isolated from each other. However, the contact plugs CT and the connection structures CS may be formed to extend to each other.

The contact plugs CT may extend along the Z direction. For example, the contact plugs CT may extend along the Z direction from the connection structures CS. Also, the contact plugs CT may extend to the inside of the first stack structure STK1 from the connection structures CS.

The contact plugs CT may be formed of tungsten (W), cobalt (Co), nickel (Ni), molybdenum (Mo), silicon (Si) or poly-silicon (poly-Si), or be formed of a combination of at least two thereof.

The contact plugs CT may be located in the first stack structure STK1. The contact plugs CT may penetrate the contact region CTR of the first stack structure STK1. The contact plugs CT extend to the inside of the first stack structure STK1, but may be spaced apart from the conductive layers CD by second spacers SP2.

The second spacers SP2 may be disposed between the contact plugs CT and the conductive layers CD. Referring to FIGS. 4A to 4C, the second spacers SP2 may surround side surfaces of the contact plugs CT. Also, the second spacers SP2 may be formed on inner walls of the conductive layers CD. For example, the second spacer SP2 may have a cylindrical shape surrounding the contact plug CT. Alternatively, the second spacer SP2 may have a cylindrical shape with a portion removed therefrom, which has a side surface extending from a side surface of the end portion P2 of the conductive layer CD.

In addition, a second spacer SP2 surrounding any one contact plug CTa may be formed in a conductive layer CDb which is not electrically connected to the contact plug CTa, and besides, a second spacer SP2 surrounding the contact plug CTa may be formed even in a conductive layer CDa electrically connected to the contact plug CTa. Therefore, the contact plug CTa may be connected to the conductive layer CDa through a connection structure CSa without being in direct contact with the conductive layer CDa.

The second spacers SP2 may insulate the contact plugs CT and the conductive layers CD from each other. For example, the second spacers SP2 may be formed of an oxide layer (e.g., a silicon oxide layer). Thus, by the second spacers SP2, two or more conductive layers CD included in the first stack structure STK1 can be prevented or mitigated from being electrically connected to any one contact plug CT.

The contact plugs CT may be located in the second stack structure STK2. The contact plugs CT may penetrate the second stack structure STK2. The contact plugs CT extend to the inside of the second stack structure STK2, but may be spaced apart from the dummy layers DL by third spacers SP3. The dummy layers DL may be floated between the contact plugs CT by the third spacers SP3. For example, each of the dummy layers DL located between the contact plugs CT is not in contact with any conductive layer.

The third spacers SP3 may be disposed between the contact plugs CT and the dummy layers DL. Referring to FIGS. 4A and 4B, the third spacers SP3 may surround side surfaces of the contact plugs CT. Also, the third spacers SP3 may be formed on inner walls of the dummy layers DL. For example, the third spacer SP3 may have a cylindrical shape surrounding the contact plug CT.

The third spacers SP3 may insulate the contact plugs CT and the dummy layers DL from each other. For example, the third spacers SP3 may be formed of an oxide layer (e.g., a silicon oxide layer). Thus, by the third spacers SP3, the dummy layers DL included in the second stack structure STK2 can be prevented or mitigated from being electrically connected to the contact plugs CT.

Because the memory device 100 includes the dummy layers DL floated between the contact plugs CT, the shape of the contact plugs CT can be prevented or mitigated from being distorted. For example, when the volume of an insulating layer (e.g., a first spacer SP1) is decreased by forming dummy layers DL on the contact region CTR of the first stack structure STK1, the shape of the contact plug CT is not distorted or a degree to which the shape of the contact plug CT is distorted can be reduced, as compared with a case where only a bulky upper insulating layer is formed without any dummy layer DL.

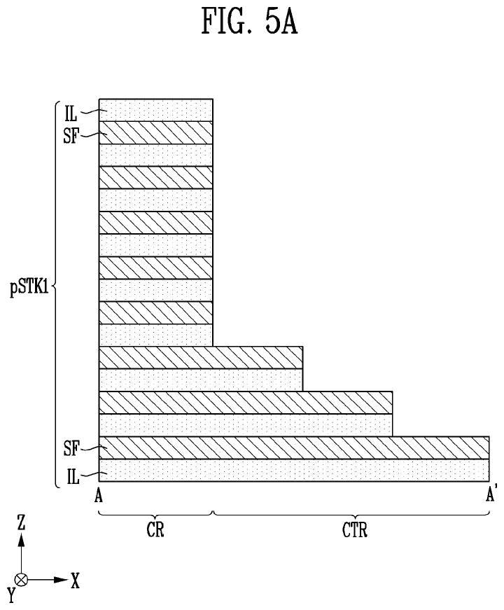

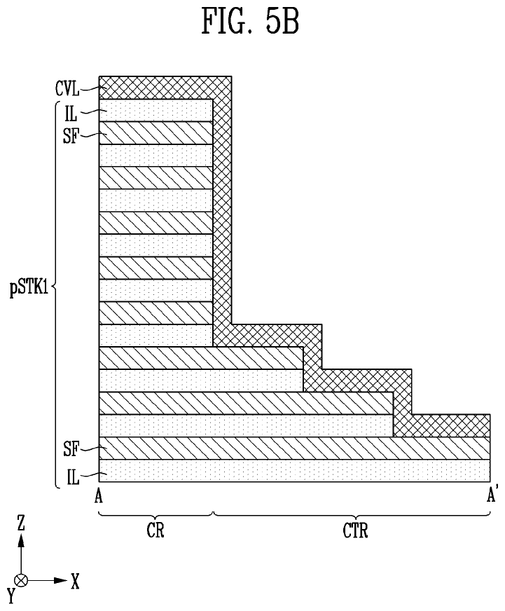

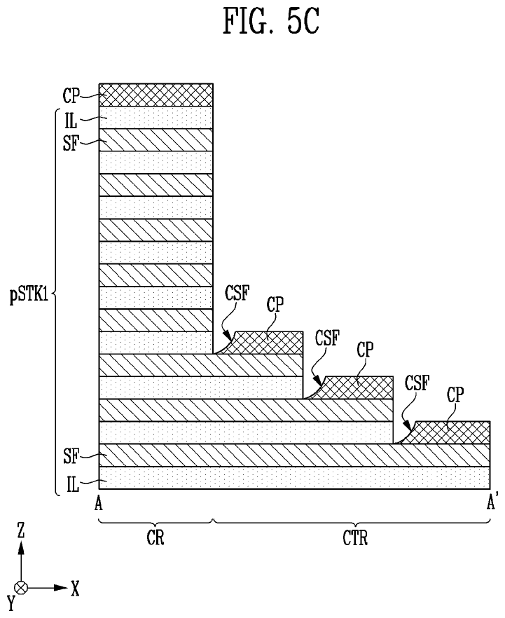

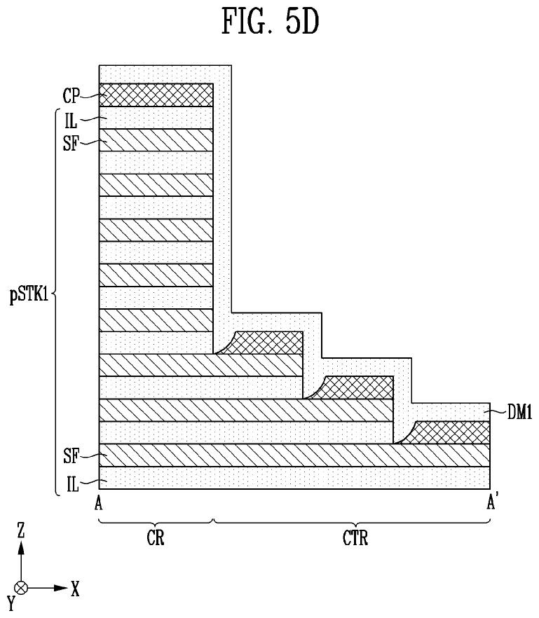

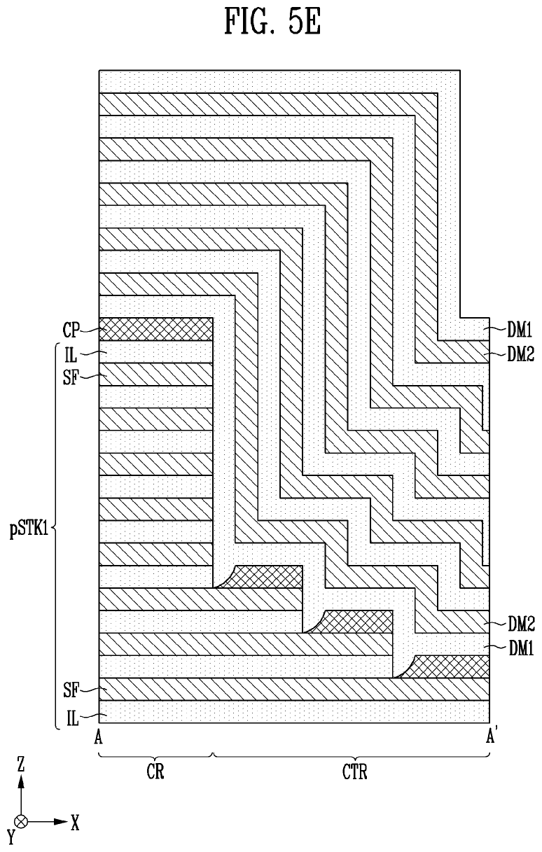

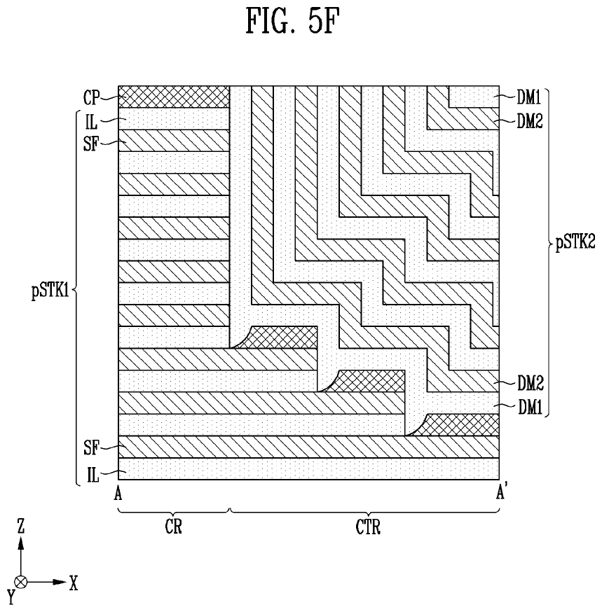

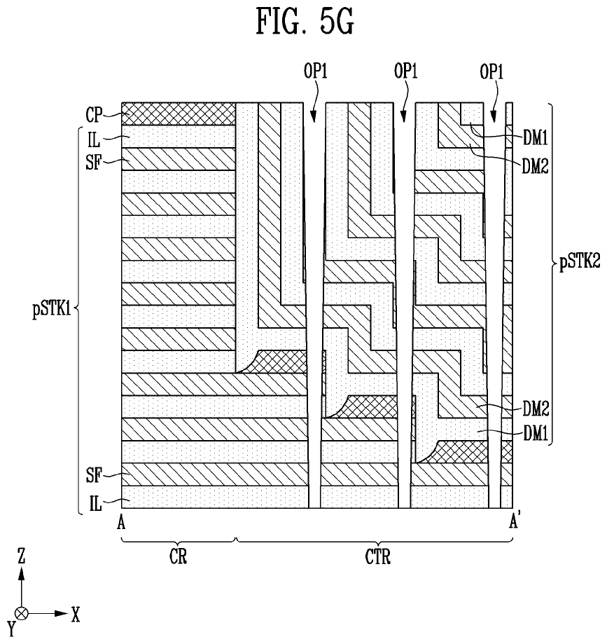

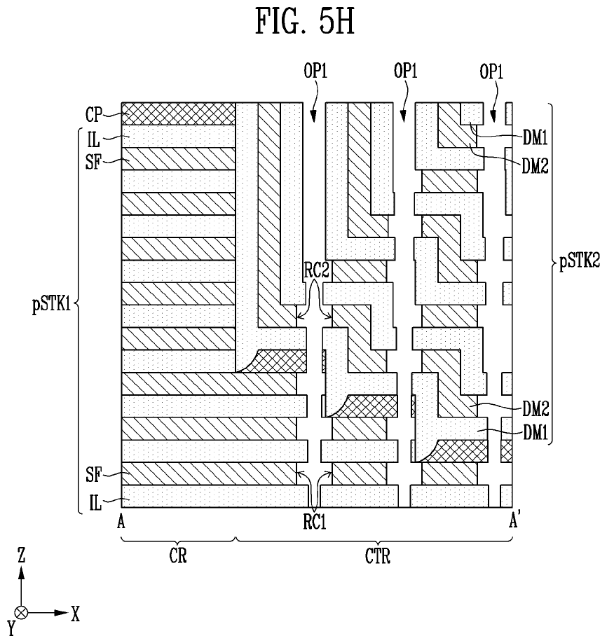

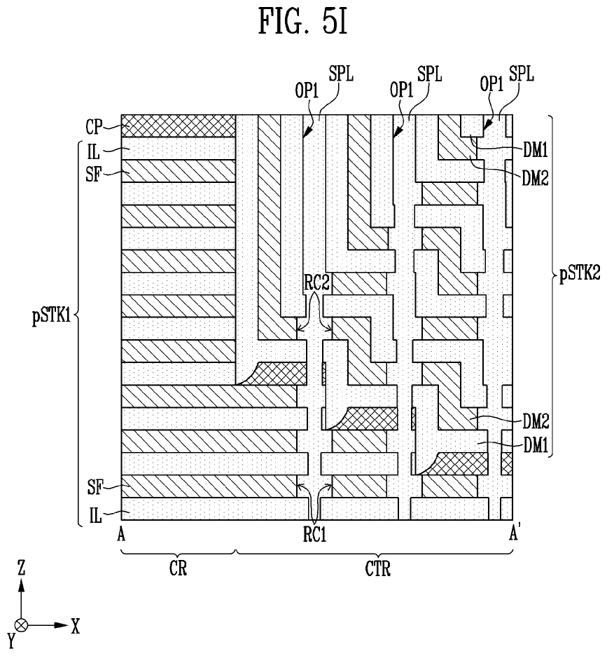

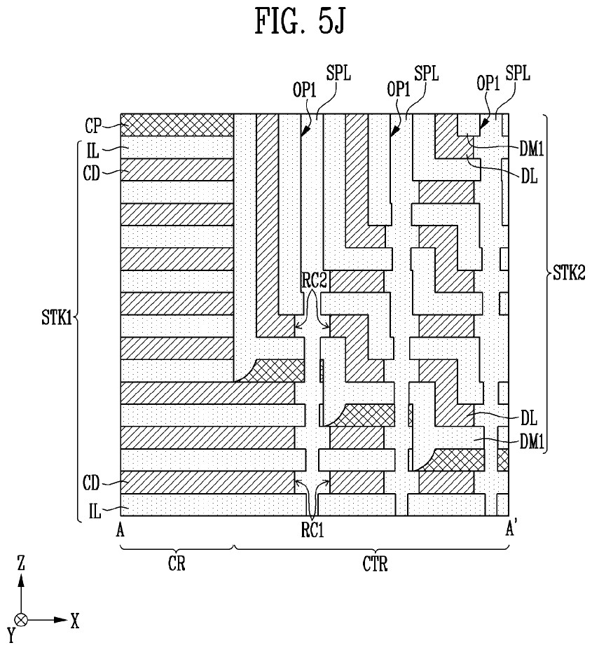

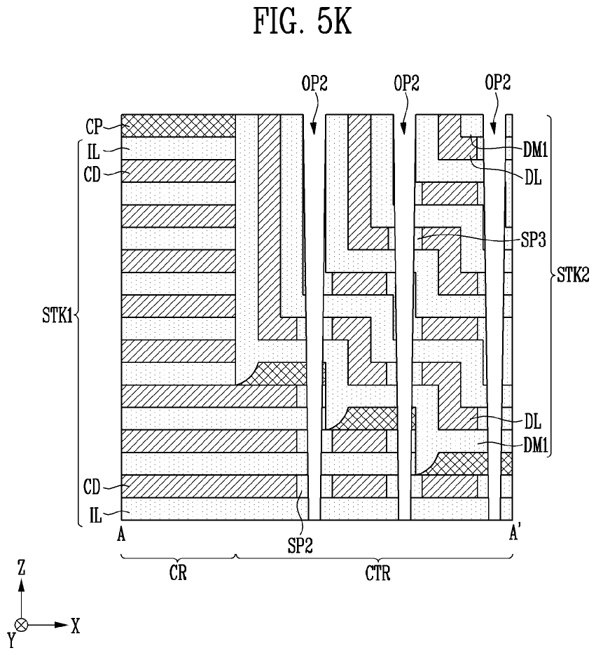

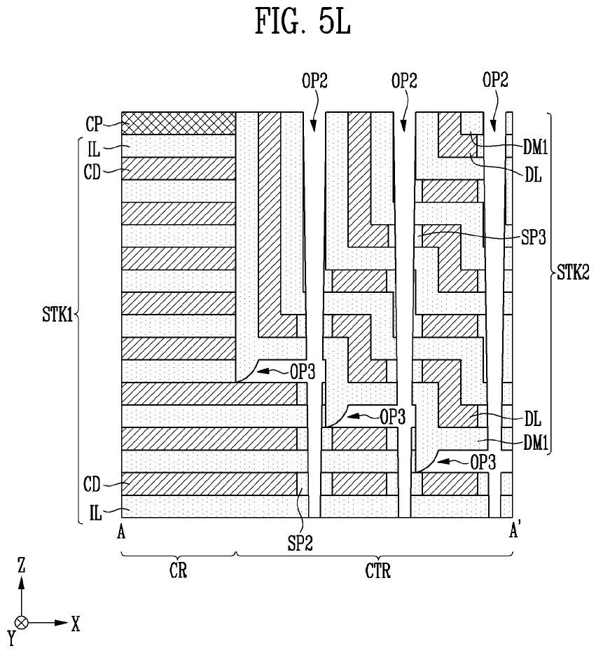

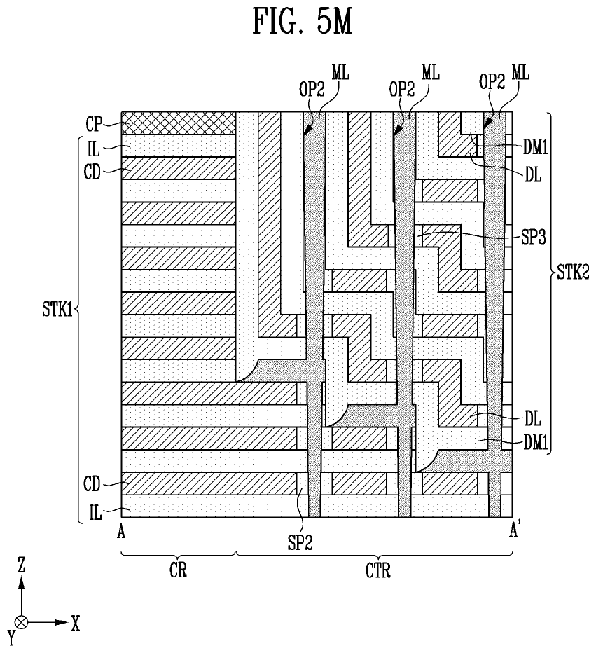

FIGS. 5A to 5M are views illustrating a manufacturing method of a memory device in accordance with an embodiment of the present disclosure. Each of FIGS. 5A to 5M illustrates the section taken along the line A-A′ shown in FIG. 3.

Referring to FIG. 5A, first material layers IL and second material layers SF may be alternately stacked. The first material layer IL may be formed of an insulating material. For example, the first material layer IL may be formed of an oxide layer (e.g., a silicon oxide layer). The second material layer SF may be formed of a material having an etch selectivity different from an etch selectivity of the first material layer IL. For example, the second material layer SF may be formed of a nitride layer.

Portions of the first material layers IL and the second material layers SF, which are alternately stacked, may be etched, thereby forming a first preliminary stack structure pSTK1 having a stepped structure. For example, portions of the first material layers IL and the second material layers SF may be defined as a cell region CR, and the other portions of the first material layers IL and the second material layers SF may be defined as a contact region CTR. The stepped structure may be formed in the contact region CTR. Some of the first material layers IL and some of the second material layers SF may be cut in the Z direction at a boundary between the cell region CR and the contact region CTR.

The first preliminary stack structure pSTK1 may have a stepped structure including first material layers IL and second material layers SF, each of which form a pair. The stepped structure may be defined by end portions of the second material layers SF. For example, the second material layers SF may be exposed through steps of the stepped structure, respectively. For example, the stepped structure may be included in the contact region CTR as shown in FIG. 5A.

Referring to FIG. 5B, a cover layer CVL may be formed on the first preliminary stack structure pSTK1. The cover layer CVL may be formed on top surfaces and side surfaces of the first preliminary stack structure pSTK1. The cover layer CVL may be formed along the top surfaces and the side surfaces of the first preliminary stack structure pSTK1. The cover layer CVL may have a thickness varying according to a position thereof. For example, a thickness of the cover layer CVL formed on the top surface of the first preliminary stack structure pSTK1 may be thicker than a thickness of the cover layer CVL formed on the side surface of the first preliminary stack structure pSTK1. The cover layer CVL may be formed of a nitride layer.

Referring to FIG. 5C, a portion of the cover layer CVL may be etched, thereby forming a cover pattern CP. The cover layer CVL on the side surface of the first preliminary stack structure pSTK1 in the entire cover layer CVL may be removed. For example, the cover layer CVL formed on the side surface of the first preliminary stack structure pSTK1 in the entire cover layer CVL may be etched, thereby forming the cover pattern CP. While the cover layer CVL formed on the top surface of the first preliminary stack structure pSTK1 may also be etched to a certain thickness. Therefore, a thickness of the cover pattern CP may be thinner than the thickness of the cover layer CVL formed on the top surface of the first preliminary stack structure pSTK1.

The cover pattern CP may be disposed on the top surfaces of the first preliminary stack structure pSTK1. The cover pattern CP may be formed on top surfaces of the end portions of the second material layers SF. For example, the cover pattern CP may be disposed along a top surface of each of the steps included in the first preliminary stack structure pSTK1. In addition, the cover pattern CP may be disposed on a region of the first preliminary stack structure pSTK1, which corresponds to the cell region CR.

Each of the cover patterns CP may include a concave surface CSF recessed from the side surface of the first preliminary stack structure pSTK1. Each of the cover patterns CP may include the concave surface CSF such that the concave surface CSF is in contact with the top surface of the first preliminary stack structure pSTK1 and is not in contact with the side surface of the first preliminary stack structure pSTK1. The concave surface CSF of each of the cover patterns CP may be formed on a side surface located in the opposite direction of the X direction among side surfaces of the cover pattern CP. While the cover layer CVL formed on the side surface of the first preliminary stack structure pSTK1 in the entire cover layer CVL is removed, a portion of the cover layer CVL formed on the top surface of the first preliminary stack structure pSTK1 in the entire cover layer CVL may be removed together, so that each of the cover patterns CP includes a recess. In FIG. 5C, it is illustrated that the section of the concave surface CSF has an arc shape (or the section of the recess has a fan shape). However, the present disclosure is not limited thereto. For example, as long as the cover patterns CP are not in contact with side surfaces of the second material layers SF, the section of the concave surface CFS may have a line shape or a curved line shape, and the section of the recess may have a triangular shape or a quadrangular shape.

Referring to FIG. 5D, a first dummy material layer DM1 may be formed, which covers the first preliminary stack structure pSTK1 and the cover pattern CP. The first dummy material layer DM1 may cover the stepped structure of the first preliminary stack structure pSTK1. The first dummy material layer DM1 may extend along the end portions of the second material layers SF on the stepped structure of the first preliminary stack structure pSTK1. Also, the first dummy material layer DM1 may cover the cover pattern CP. The first dummy material layer DM1 may fill the recess which the cover pattern CP has. The first dummy material layer DM1 may be formed of an insulating material. For example, the first dummy material layer DM1 may be formed of an oxide layer (e.g., a silicon oxide layer).

Referring to FIG. 5E, second dummy material layers DM2 and first dummy material layers DM1 may be alternately stacked on the first dummy material layer DM1 formed in FIG. 5D. For example, after the first dummy material layer DM1 formed in FIG. 5D is formed, a second dummy material layer DM2 may be formed, which covers the first dummy material layer DM1. The second dummy material layer DM2 may be conformally formed on the first dummy material layer DM1. Subsequently, first dummy material layers DM1 and second dummy material layers DM2 may be alternately deposited. The second dummy material layer DM2 may be formed of a material which can be selectively removed in a subsequent process. The second dummy material layer DM2 may be formed of a material having an etch selectivity different from an etch selectivity of the first dummy material layer DM1. For example, the second dummy material layer DM2 may be formed of a nitride layer.

Each of the first dummy material layers DM1 and the second dummy material layers DM2 may extend along the end portions of the second material layers SF on the stepped structure of the first preliminary stack structure pSTK1. For example, each of the first dummy material layers DM1 and the second dummy material layers DM2 may have a stepped shape corresponding to the stepped structure of the first preliminary stack structure pSTK1.

Referring to FIG. 5F, portions of the first dummy material layers DM1 and the second dummy material layers DM2, which are formed on the first preliminary stack structure pSTK1, may be removed, thereby forming a second preliminary stack structure pSTK2. Regions formed at levels higher than a specific level among the first dummy material layers DM1 and the second dummy material layers DM2, which are formed in FIG. 5E, may be removed. For example, after a deposition process performed in FIG. 5E, a chemical mechanical polishing (CMP) process may be performed until the cover pattern CP (e.g., the cover pattern CP on the top end of the first material layer IL) is exposed.

Referring to FIG. 5G, first openings OP1 may be formed in the entire structure including the first preliminary stack structure pSTK1 and the second preliminary stack structure pSTK2. For example, the first openings OP1 may be formed, which penetrate the first preliminary stack structure pSTK1 and the second preliminary stack structure pSTK2. The first openings OP1 may penetrate the first and second preliminary stack structures pSTK1 and pSTK2 and the cover patterns CP. For example, the first openings OP1 may penetrate the cover patterns CP on the stepped structure, respectively. Inner walls of the first and second preliminary stack structures pSTK1 and pSTK2 and inner walls of the cover patterns CP may be exposed through the first openings OP1. That is, the first and second material layers IL and SF and the first and second dummy material layers DM1 and DM2 may be exposed through the first openings OP1. The first openings OP1 may substantially have the same depth. An anisotropic dry etching process may be performed to form the first openings OP1 at specified positions.

Referring to FIG. 5H, portions of the second material layers SF and the second dummy material layers DM2, which are exposed through the first openings OP1, may be removed. The second material layers SF and the second dummy material layer DM2 among the first and second material layers IL and SL, the first and second dummy material layers DM1 and DM2, and the cover patterns CP, which are exposed through the first openings OP1, may be selectively etched. For example, a portion of each of the second material layers SF exposed through the first openings OP1 may be removed, thereby forming first recesses RC1. In addition, a portion of each of the second dummy material layers DM2 exposed through the first openings OP1, thereby forming second recesses RC2.

Referring to FIG. 5I, a spacer layer SPL may be formed in the first openings OP1 and the recesses RC1 and RC2. The spacer layer SPL may be formed, which fills the first openings OP1, the first recesses RC1, and the second recesses RC2. The spacer layer SPL may be formed of an insulating material. For example, the spacer layer SPL may be formed of an oxide layer (e.g., a silicon oxide layer).

Referring to FIG. 5J, the second material layers SF of the first preliminary stack structure pSTK1 may be replaced with third material layers CD, and the second dummy material layers DM2 of the second preliminary stack structure pSTK2 may be replaced with third dummy material layers DL. In a state in which the spacer layer SPL is filled in the first openings OP1, the first recesses RC1, and the second recesses RC2, some of the material layers of the first and second preliminary stack structures pSTK1 and pSTK2 may be replaced. For example, the second material layers SF and the second dummy material layers DM2 may be removed through the slit S1 shown in FIG. 3, and the third material layers CD and the third dummy material layers DL may be formed through the slit S1 shown in FIG. 3. The third material layers CD and the third dummy material layers DL may be formed of tungsten (W), cobalt (Co), nickel (Ni), molybdenum (Mo), silicon (Si) or poly-silicon (poly-Si), or be formed of a combination of at least two thereof.

As the second material layers SF are replaced with the third material layers CD, a first stack structure STK1 may be formed, in which the first material layers IL and the third material layers CD are alternately stacked. The first material layers IL may correspond to the interlayer insulating layers IL shown in FIG. 4A, and the third material layers CD may correspond to the conductive layers CD shown in FIGS. 4A to 4C.

As the second dummy material layers DM2 are replaced with the third dummy material layers DL, a second stack structure STK2 may be formed, in which the first dummy material layers DM1 and the third dummy material layers DL are alternately stacked. The first dummy material layers DM1 may correspond to the first spacers SP1 shown in FIG. 4A, and the third dummy material layers DL may correspond to the dummy layers DL shown in FIGS. 4A and 4B.

Referring to FIG. 5K, second openings OP2 may be formed, which penetrate the spacer layer SPL. The second openings OP2 may penetrate the first and second stack structures STK1 and STK2. The spacer layers SPL remaining after the second openings OP2 are formed among the spacer layers SPL formed in FIG. 5J may become second spacers SP2 or third spacers SP3. The third material layers CD may be spaced apart from the second openings OP2 by the second spacers SP2. In addition, the third dummy material layer DL may be spaced apart from the second openings OP2 by the third spacers SP3. Therefore, the third material layers CD and the third dummy material layers DL might not be exposed through the second openings OP2.

The cover patterns CP may be exposed through the second openings OP2. For example, inner walls of the cover patterns CP may be exposed through the second openings OP2. A width of the second openings OP2 may be greater than or equal to a width of the first openings OP1. For example, a width with which the second opening OP2 penetrates the cover pattern CP may be greater than or equal to a width with which the first opening OP1 penetrates the cover pattern CP.

The shape of the second openings OP2 may be relatively constantly formed by the third dummy material layers DL floated between the second openings OP2. For example, when the third dummy material layers DL exist, the sectional shape of the second opening OP2 might not vary at a certain level or more according to a height or the sectional size of the second opening OP2 might not vary at a certain level or more according to a height, as compared with the third dummy material layers DL do not exist.

Referring to FIG. 5L, the cover patterns CP exposed through the second openings OP2 may be removed. Cover patterns CP in contact with top surfaces of the third material layers CD among the cover patterns CP on the first stack structure STK1 may be removed. Only the cover patterns CP among the first material layers IL, the first dummy material layers DM1, the second spacers SP2, the third spacers SP3, and the cover patterns CP, which are exposed through the second openings OP2, may be selectively etched. An isotropic wet etching process may be performed to etch the cover patterns CP.

As the cover patterns CP are removed, third openings OP3 may be formed. The third openings OP3 may extend from the second openings OP2. The third openings OP3 may extend in a horizontal direction from the second openings OP2. Portions of the top surfaces of the third material layers CD may be exposed by the third openings OP3. For example, top surfaces of a stepped structure of the first stack structure STK1 may be exposed through the third openings OP3.

Referring to FIG. 5M, a conductive material ML may be formed in the second openings OP2 and the third openings OP3. The conductive material ML may fill the second openings OP2 and the third openings OP3. The conductive material ML may be in contact with the top surfaces of the third material layers CD. Also, the conductive material ML may be spaced apart from the third dummy material layers DL. The third dummy material layer DL may be floated between the conductive materials ML. In an embodiment, the third dummy material layer DL may be floated between the conductive materials ML as shown in FIG. 5M. In an embodiment, the third dummy material layer DL may be located between the conductive materials ML. In an embodiment, the third dummy material layer DL may be located between the conductive materials ML and spaced apart from the conductive materials ML. In an embodiment, the third dummy material layer DL may be located between the conductive materials ML and not in direct contact with the conductive materials ML as shown in FIG. 5M. In an embodiment, the third dummy material layers DL may be located between the conductive materials ML, not in direct contact with the conductive materials ML, and located directly on the first dummy material layers DM1. In an embodiment, the third dummy material layers DL may be located between the conductive materials ML, not in direct contact with the conductive materials ML, and located directly on the first dummy material layers DM1 to appear as being floated between the conductive materials ML as shown in FIG. 5M. The conductive material ML may be formed of tungsten (W), cobalt (Co), nickel (Ni), molybdenum (Mo), silicon (Si) or poly-silicon (poly-Si), or be formed of a combination of at least two thereof. In an embodiment, at least one third dummy material layer DL among the third dummy material layers DL has a stepped shape corresponding to the stepped structure of the first stack structure STK1 as shown in FIGS. 4A and 5M (i.e., dummy layer DL located in the Z direction above either connection structure CSa or connection structure CSb). For example, in an embodiment, the ‘Z’ shaped dummy layer DL located directly above connection structure CSa or connection structure CSb in FIG. 4A may be identified as one third dummy material layer DL among the third dummy material layers DL having the stepped shape corresponding to the stepped structure of the first stack structure STK1.

A portion of the conductive material ML, which is filled in the second opening OP2, may be designated as the contact plug CT shown in FIGS. 4A to 4C. In addition, a portion of the conductive material ML, which is filled in the third opening OP3, may be designated as the connection structure CS shown in FIGS. 4A and 4B. In an embodiment, the contact plugs CT are electrically isolated from the third dummy material layers DL or dummy layers DL.

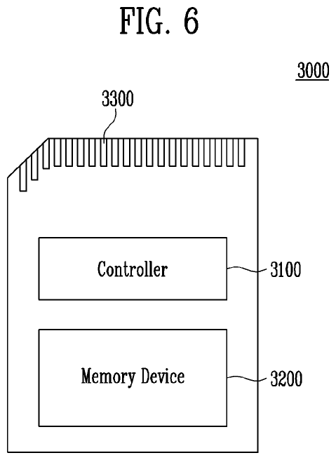

FIG. 6 is a diagram illustrating a memory card system to which the memory device of the present disclosure is applied.

Referring to FIG. 6, the memory card system 3000 may include a controller 3100, a memory device 3200, and a connector 3300.

The controller 3100 may be connected to the memory device 3200. The controller 3100 may access the memory device 3200. For example, the controller 3100 may control a program, read or ease operation, or control a background operation of the memory device 3200. The controller 3100 may provide an interface between the memory device 3200 and a host. The controller 3100 may drive firmware for controlling the memory device 3200. For example, the controller 3100 may include components such as a Random Access Memory (RAM), a processing unit, a host interface, a memory interface, and an error corrector.

The controller 3100 may communicate with an external device through the connector 3300. The controller 3100 may communicate with the external device (e.g., the host) according to a specific communication protocol. For example, the controller 3100 may communicate with the external device through at least one of various communication protocols such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), firewire, a Universal Flash Storage (UFS), Wi-Fi, Bluetooth, and NVMe. For example, the connector 3300 may be defined by at least one of the above-described various communication protocols.

The memory device 3200 may include memory cells, and be configured identically to the memory device 100 shown in FIG. 1.

The controller 3100 and the memory device 3200 may be integrated into a single semiconductor device, to constitute a memory card. For example, the controller 3100 and the memory device 3200 may constitute a memory card such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro and eMMC), an SD card (SD, miniSD, microSD and SDHC), and a Universal Flash Storage (UFS).

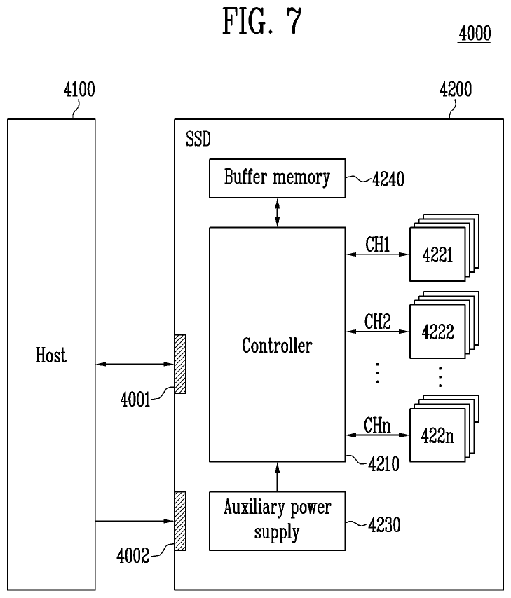

FIG. 7 is a diagram illustrating a Solid State Drive (SSD) system to which the memory device of the present disclosure is applied.

Referring to FIG. 7, the SSD system 4000 may include a host 4100 and an SSD 4200. The SSD 4200 may exchange a signal with the host 4100 through a signal connector 4001, and receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. Exemplarily, the signal may be a signal based on an interface between the host 4100 and the SSD 4200. For example, the signal may be a signal defined by at least one of interfaces such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive power input from the host 4100 and charge the power. When the supply of power from the host 4100 is not smooth, the auxiliary power supply 4230 may provide power of the SSD 4200. For example, the auxiliary power supply 4230 may be located in the SSD 4200, or be located at the outside of the SSD 4200. For example, the auxiliary power supply 4230 may be located on a main board, and provide auxiliary power to the SSD 4200.

The buffer memory 4240 may operate as a buffer memory of the SSD 4200. For example, the buffer memory 4240 may store data received from the host 4100 or data received from the plurality of memory devices 4221 to 422n, or store meta data (e.g., a mapping table) of the memory devices 4221 to 422n. The buffer memory 4240 may include volatile memories such as a DRAM, an SDRAM, a DDR SDRAM, an LPDDR SDRAM, and a GRAM or nonvolatile memories such as a FRAM, a ReRAM, an STT-MRAM, and a PRAM.

In accordance with an embodiment of the present disclosure, a dummy layer is formed inside an upper insulating layer formed in a contact region of the memory device, so that distortion of the shape of a contact plug can be prevented or mitigated.

While the present disclosure has been shown and described with reference to certain examples of embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a first stack structure including conductive layers stacked along a first direction, the first stack structure having a stepped structure defined by end portions of the conductive layers;
contact plugs respectively connected to the conductive layers, the contact plugs extending along the first direction, the contact plugs extending to the inside of the first stack structure; and
dummy layers located between the contact plugs.

2. The memory device of claim 1, wherein the dummy layers are located on the stepped structure of the first stack structure.

3. The memory device of claim 1, further comprising first spacers alternately stacked with the dummy layers.

4. The memory device of claim 3, wherein the dummy layers and the first spacers extend along the end portions of the conductive layers, respectively.

5. The memory device of claim 3, wherein the dummy layers and the first spacers constitute a second stack structure overlapping the stepped structure of the first stack structure.

6. The memory device of claim 1, wherein at least one dummy layer among the dummy layers has a stepped shape corresponding to the stepped structure.

7. The memory device of claim 1, wherein the first stack structure further includes interlayer insulating layers stacked between the conductive layers.

8. The memory device of claim 1, wherein the contact plugs are spaced apart from the conductive layers, respectively.

9. The memory device of claim 1, further comprising second spacers between the contact plugs and the conductive layers.

10. The memory device of claim 1, further comprising connection structures respectively in contact with top surfaces of the end portions of the conductive layers,
wherein the contact plugs are in contact with the connection structures, respectively.

11. The memory device of claim 10, wherein the contact plugs are connected to the conductive layers through the connection structures.

12. The memory device of claim 10, wherein each of the connection structures includes a concave surface recessed from a side surface of the first stack structure.

13. The memory device of claim 1, wherein the dummy layers include a conductive material.

14. The memory device of claim 1, further comprising third spacers located between the contact plugs and the dummy layers.

15. The memory device of claim 1, wherein the contact plugs and the dummy layers are electrically isolated from each other.
